(19) United States
(12) Patent Application Publication
(10) Pub. No.: US 2023/0033603 A1
(43) Pub. Date: Feb. 2, 2023

(54) SEMICONDUCTOR STRUCTURE AND FABRICATION METHOD THEREOF

(71) Applicant: Semiconductor Technology Innovation Center (Beijing) Corporation, Beijing (CN)

(72) Inventor: Han WANG, Beijing (CN)

(21) Appl. No.: 17/875,845

(22) Filed: Jul. 28, 2022

(30) Foreign Application Priority Data
Jul. 28, 2021 (CN) 202110855630.7

(51) Int. Cl. H01L 29/423; H01L 29/786; H01L 29/06; H01L 29/417; H01L 29/66

(52) U.S. Cl. CPC H01L 29/42392; H01L 29/0673; H01L 29/6653; H01L 29/6656; H01L 29/41775; H01L 29/66545; H01L 29/66553; H01L 29/78696

(57) ABSTRACT

A semiconductor structure and a fabrication method are provided. The semiconductor structure includes: a substrate; channel layers on the substrate vertically stacked along a normal direction of a surface of the substrate and extend along a first direction parallel to the surface of the substrate; an isolation layer over the substrate; isolation grooves between ends of adjacent channel layers; inner spacers in the isolation grooves vertically isolating channel layers; gate structures over the isolation layer surrounding a portion of channel layers along a second direction perpendicular to the first direction; outsider spacers at sidewalls of the gate structures; source/drain doped layers at two sides of each gate structure; and a dielectric layer over the isolation layer covering a portion of the channel layers and the gate structures and exposes top surfaces of the gate structures.

### CROSS-REFERENCE TO RELATED APPLICATION

This application claims the priority of Chinese Patent Application No. 202110855630.7, filed on Jul. 28, 2021, the content of which is incorporated herein by reference in its entirety.

### TECHNICAL FIELD

The present disclosure generally relates to the field of semiconductor fabrication technology and, more particularly, relates to a semiconductor structure and its fabrication method.

### BACKGROUND

A Metal-Oxide-Semiconductor Field Effect Transistor (MOSFET) is one of the most important components in modern integrated circuits. A basic structure of a MOSFET includes: a semiconductor substrate; gate structures on a surface of the semiconductor substrate; and source/drain doped regions in the semiconductor substrate at two sides of each gate structure. Each gate structure includes a gate dielectric layer on the surface of the semiconductor substrate and a gate electrode layer on a surface of the gate dielectric layer.

With the continuous development of semiconductor technologies, a size of a gate structure is further reduced. A conventional fin field effect transistor has limitations in pinch-off of an off-state current, and also has limitations in increasing an operating current. Specifically, the conventional fin field effect transistor only controls a channel through a three-sided gate and the channel region has only an area of a fin near a top surface and a sidewall, which is not beneficial to the gate for controlling the channel. At the same time, a volume in the fin used as the channel region is relatively small, which limits the increase of the operating current of the fin field effect transistor. Therefore, a MOSFET with a gate-all-around (GAA) structure is proposed, which not only enables the gate to control the channel in all directions for further reducing the off-state current but also increases the volume used as the channel region to increase the operating current of the GAA structure MOSFET.

### SUMMARY

One aspect of the present disclosure provides a semiconductor structure. The semiconductor structure includes: a substrate; a plurality of channel layers on the substrate vertically stacked along a normal direction of a surface of the substrate and extend along a first direction parallel to the surface of the substrate; an isolation layer on the substrate, where a top surface of the isolation layer is not higher than a top surface of any of the plurality of channel layers at bottom; isolation grooves between ends of adjacent channel layers of the plurality of channel layers; inner spacers in the isolation grooves vertically isolating the plurality of channel layers along the normal direction of the surface of the substrate such that the adjacent channel layers are suspended; gate structures over the isolation layer surrounding a portion of the plurality of channel layers along a second direction perpendicular to the first direction and parallel to the surface of the substrate; outsider spacers at sidewalls of the gate structures, where sidewalls of the outside spacers are recessed with respect to end surfaces of the plurality of channel layers; source/drain doped layers at two sides of each gate structure, where surfaces of the source/drain doped layers, surfaces of the inner spacers, and the end surfaces of the plurality of channel layers are vertically coplanar; and a dielectric layer over the isolation layer, where the dielectric layer covers a portion of the plurality of channel layers and the gate structure and exposes top surfaces of the gate structures.

Optionally, each of the isolation grooves includes a first corner groove, a middle groove, and a second corner groove arranged along the second direction; and each of a size of the first corner groove and a size of the second corner groove along the first direction is larger than a size of the middle groove along the first direction.

Optionally, each of the inner spacers includes a first corner layer in the first corner groove, a middle layer in the middle groove, and a second corner layer in the second corner groove.

Optionally, the sidewalls of the outer spacers are recessed with respect to the end surfaces of the plurality of channel layers by about 1 nm to about 5 nm.

Optionally, the inner spacers are made of a material including silicon nitride.

Another aspect of the present disclosure provides a fabrication method for forming a semiconductor structure. The method includes: providing a substrate; forming a plurality of initial channel layers and a plurality of initial sacrificial layers on the substrate, where the plurality of initial channel layers and the plurality of initial sacrificial layers are stacked vertically and alternately along a normal direction of a surface of the substrate and extend along a first direction parallel to the surface of the substrate; forming an isolation layer on the substrate, where a top surface of the isolation layer is not higher than a top surface of one of the plurality of initial channel layers at bottom; forming dummy gate structures over the substrate and initial outer spacers on sidewall surfaces of the dummy gate structures, where the dummy gate structure crosses a portion of the plurality of initial channel layers and a portion of the plurality of initial sacrificial layers along a second direction perpendicular to the first direction and parallel to the surface of the substrate; using the dummy gate structures and the initial outer spacers as a mask to etch a portion of the plurality of initial channel layers and a portion of the plurality of the initial sacrificial layers, to form source/drain openings, a plurality of channel layers, and plurality of sacrificial layers; after forming the source/drain openings, thinning the initial outer spacers to form outer spacers, where a size of the outer spacers parallel to the first direction is smaller than a size of the initial outer spacers parallel to the first direction; etching back a part of the plurality of sacrificial layers exposed by the source/drain openings, to forming isolation grooves between adjacent channel layers; forming inner spacers in the isolation grooves; forming source/drain doped layers in the source/drain openings, where surfaces of the source/drain doped layers, surfaces of the inner spacers and end faces of the plurality of channel layers are vertically coplanar; and forming a dielectric layer over the isolation layer, where the dielectric layer covers a portion of the plurality of channel layers and the dummy gate structure and exposes top surfaces of the dummy gate structures.

Optionally, each of the isolation grooves includes a first corner groove, a middle groove, and a second corner groove arranged along the second direction; and each of a size of the first corner groove and a size of the second corner groove along the first direction is larger than a size of the middle groove along the first direction.

Optionally, each of the inner spacers includes a first corner layer in the first corner groove, a middle layer in the middle groove, and a second corner layer in the second corner groove.

Optionally, the size of the outer spacers parallel to the first direction is smaller than the size of the initial outer spacers parallel to the first direction by about 1 nm to about 5 nm.

Optionally, the initial outer spacers are thinned by an isotropic etching process.

Optionally, forming the inner spacers includes: forming first initial inner spacers in the isolation grooves, on sidewalls and bottom surfaces of the source/drain openings, on the sidewalls of the outer spacers, and on top surfaces of the dummy gate structures; etching back the first initial inner spacers until the bottom surface of the source/drain openings and the top surfaces of the dummy gate structures are exposed, to form second initial inner spacers; and etching back the second initial inner spacers until the sidewalls of the outer spacers and the plurality of channel layers are exposed, to form the inner spacers.

Optionally, the first initial inner spacers are formed by a physical vapor deposition process, a chemical vapor deposition process, or an atomic layer deposition process.

Optionally, the first initial inner spacers are made of a material including silicon nitride.

Optionally, after forming the dielectric layer, the method further includes: removing the dummy gate structures to form gate openings in the dielectric layer; removing a portion of the plurality of sacrificial layers exposed by the gate openings to form gate grooves between adjacent channel layers; and forming a gate structure in each gate opening and a corresponding gate groove, where the gate structure surrounds a corresponding one of the plurality of channel layers.

Optionally, the plurality of sacrificial layers and the plurality of channel layers are made of different materials.

Optionally, the plurality of sacrificial layer is made of a material including silicon germanium; and the plurality of channel layers is made of a material including silicon.

The semiconductor structure provided by various embodiments of the present disclosure may include the outsider spacers at the sidewalls of the gate structures and the sidewalls of the outside spacers are recessed with respect to end surfaces of the plurality of channel layers. By thinning the initial outer spacers, the formed outer spacers may expose other two surfaces of each of the plurality of sacrificial layers. Correspondingly, when some of the plurality of sacrificial layers are etched subsequently, three surfaces of each of the plurality of sacrificial layers may be also etched. The difficulty of the etching process and the residue of etching by-products may be reduced, and morphology of the subsequently formed isolation grooves may be improved.

Further, since the sidewalls of the outer spacers may be recessed with respect to the end surfaces of the plurality of channel layers, the outer spacers may expose other two sides of each of the plurality of channel layers, therefore ensuring contact areas between the source/drain doped layers and the plurality of channel layers are increased to improve the working current of the device.

Each of the isolation grooves may include a first corner groove, a middle groove, and a second corner groove arranged along the second direction. A size of the first corner groove and a size of the second corner groove along the first direction may be larger than a size of the middle groove along the first direction. Each inner spacer may include a first corner layer in the first corner groove, a middle layer in the middle groove, and a second corner layer in the second corner groove. Since the difficulty of etching is reduced, the formed first corner groove and the second corner groove may have relatively large dimensions, and then dimensions of the first corner layer in the first corner groove and the second corner layer in the second corner groove of the inner spacer may be relatively large. Correspondingly, the isolation effect of the inner spacer may be effectively improved, and the occurrence of the leakage problem between the gate structures and the source/drain doped layers formed subsequently may be reduced.

The sidewalls of the outer spacers may be recessed with respect to the end surfaces of the plurality of channel layers by about 1 nm to about 5 nm. When the sidewalls of the outer spacers are recessed with respect to the end surfaces of the plurality of channel layers by a range less than 1 nm, areas of the other two surfaces of each of the plurality of sacrificial layers exposed by the outer spacers may be small, and the morphology of the subsequently formed isolation grooves may still have defects. When the sidewalls of the outer spacers are recessed with respect to the end surfaces of the plurality of channel layers by a range larger than 5 nm, a remaining thickness of the outer spacers may be small, and the isolation effect of the outer spacers may be affected, easily leading to the leakage problem between adjacent gate structures.

In the fabricating method of a semiconductor structure provided by various embodiments of the present disclosure, after forming the source/drain openings, the initial outer spacers may be thinned to form the outer spacers. The dimensions of the outer spacers along the first direction may be smaller than the dimensions of the initial outer spacers along the first direction. By thinning the initial outer spacers, the formed outer spacers may expose other two surfaces of each of the plurality of sacrificial layers. Correspondingly, when some of the plurality of sacrificial layers are etched subsequently, the etching may easily be in contact with the three surfaces of each of the plurality of sacrificial layers. The difficulty of the etching process and the residue of etching by-products may be reduced, and morphology of the subsequently formed isolation grooves may be improved.

Further, since the sidewalls of the outer spacers may be recessed with respect to the end surfaces of the plurality of channel layers, the outer spacers may expose other two sides of each of the plurality of channel layers, therefore ensuring contact areas between the source/drain doped layers and the plurality of channel layers are increased to improve the working current of the device.

Each of the isolation grooves may include a first corner groove, a middle groove, and a second corner groove arranged along the second direction. A size of the first corner groove and a size of the second corner groove along the first direction may be larger than a size of the middle groove along the first direction. Each inner spacer may include a first corner layer in the first corner groove, a middle layer in the middle groove, and a second corner layer in the second corner groove. Since the difficulty of etching is reduced, the formed first corner groove and the second corner groove may have relatively large dimensions, and then dimensions of the first corner layer in the first corner groove and the second corner layer in the second corner groove of the inner spacer may be relatively large. Correspondingly, the isolation effect of the inner spacer may be effectively improved, and the occurrence of the leakage problem between the gate structures and the source/drain doped layers formed subsequently may be reduced.

The sidewalls of the outer spacers may be recessed with respect to the end surfaces of the plurality of channel layers by about 1 nm to about 5 nm. When the sidewalls of the outer spacers are recessed with respect to the end surfaces of the plurality of channel layers by a range less than 1 nm, areas of the other two surfaces of each of the plurality of sacrificial layers exposed by the outer spacers may be small, and the morphology of the subsequently formed isolation grooves may still have defects. When the sidewalls of the outer spacers are recessed with respect to the end surfaces of the plurality of channel layers by a range larger than 5 nm, a remaining thickness of the outer spacers may be small, and the isolation effect of the outer spacers may be affected, easily leading to the leakage problem between adjacent gate structures.

### BRIEF DESCRIPTION OF THE DRAWINGS

The following drawings are merely examples for illustrative purposes according to various disclosed embodiments and are not intended to limit the scope of the present disclosure.

FIGS. 1-2 illustrate semiconductor structures corresponding to certain stages for forming a semiconductor structure;

FIGS. 3-17 illustrate semiconductor structures corresponding to certain stages of forming an exemplary semiconductor structure according to various disclosed embodiments of the present disclosure; and

FIG. 18 illustrates an exemplary method for forming a semiconductor structure according to various disclosed embodiments of the present disclosure.

### DETAILED DESCRIPTION

Reference will now be made in detail to exemplary embodiments of the disclosure, which are illustrated in the accompanying drawings. Wherever possible, the same reference numbers will be used throughout the drawings to refer to the same or like parts.

It should be noted that “surface” or “upper” in this specification are used to describe the relative positional relationship in space, and are not limited to whether they are in direct contact.

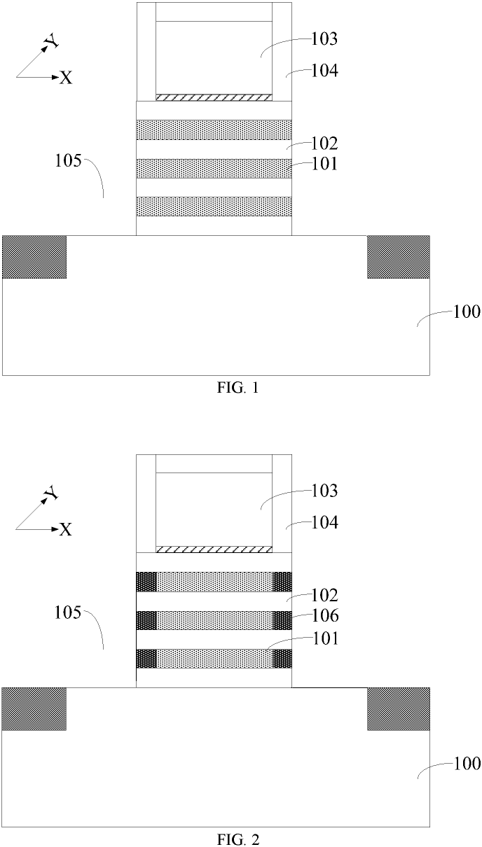

FIGS. 1-2 illustrate semiconductor structures corresponding to certain stages for forming a semiconductor structure.

As shown in FIG. 1, a substrate 100 is provided. A plurality of initial sacrificial layers on the substrate 100 and overlapping along a normal direction of a surface of the substrate 100, and an initial channel layer (not shown in the figure) between two adjacent initial sacrificial layers are provided. The plurality of initial sacrificial layers and initial channel layers extend along a first direction X. Dummy gate structures 103 are formed on the substrate 100. The dummy gate structures 103 cross some of the plurality of initial sacrificial layers and the initial channel layers along a second direction Y. The second direction Y is perpendicular to the first direction X. Outside spacers 104 are formed on sidewalls of the dummy gate structures 103. Some of the plurality of initial sacrificial layers and the initial channel layers are etched using the dummy gate structures 103 and the outside spacers 104 as a mask, to form source/drain openings 105, a plurality of sacrificial layers 101, and a plurality of channel layers 102.

As shown in FIG. 2, a portion of the plurality of sacrificial layers 101 exposed by the source/drain openings 105 is etched, to form isolation grooves between adjacent channel layers 102, and inside spacers 106 are formed in the isolation grooves.

After etching some initial sacrificial layers and some initial channel layers using the dummy gate structure 103 and the outer spacers 104 as the mask, only one side of each of the plurality of sacrificial layers 101 is exposed. one side. when etching the portion of the plurality of sacrificial layers 101 exposed by the source/drain openings 105, the etching solution can only contact one surface of each of the plurality of sacrificial layers 101. Correspondingly, the etching process is difficult and easily leads to etching by-product residuals. Also, the morphology of the formed isolation grooves is not good. The depth of corner regions of the isolation grooves is small, such that the inner spacers 106 located in the corner regions cannot have a good isolation effect, and it is easy to cause a leakage problem between the gate structures and the source/drain doped layers subsequently.

The present disclosure provides a semiconductor structure and its fabrication method. By performing an etching-back process on initial outer spacers, formed outer spacers may expose other two surfaces of each sacrificial layer. Subsequently, when etching back a portion of the sacrificial layer, etching may be easily in contact with three surfaces of the sacrificial layer, therefore reducing the difficulty of etching the sacrificial layer.

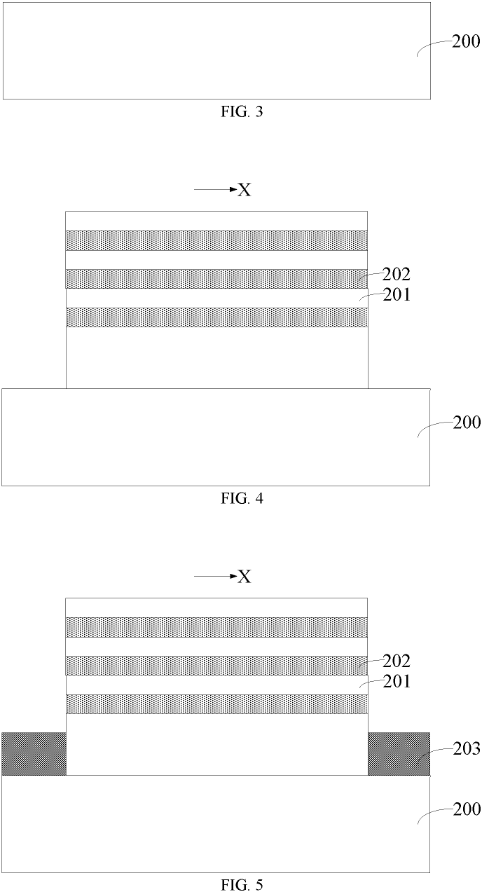

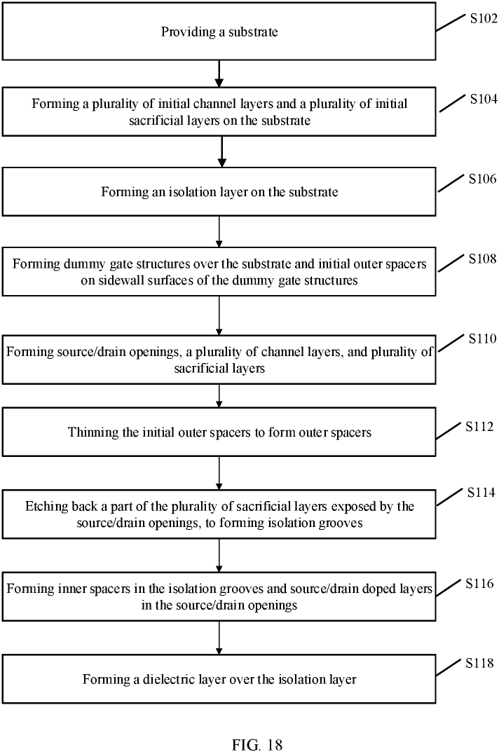

FIGS. 3-17 illustrate semiconductor structures corresponding to certain stages of forming an exemplary semiconductor structure according to various disclosed embodiments of the present disclosure; and FIG. 18 illustrates an exemplary method for forming a semiconductor structure according to various disclosed embodiments of the present disclosure.

As shown in FIG. 3, a substrate 200 may be provided (e.g., S102 in FIG. 18).

In one embodiment, the substrate 200 may be made of silicon.

As shown in FIG. 4, a plurality of initial channel layers 201 and a plurality of initial sacrificial layers 202 may be formed on the substrate 200 (e.g., S104 in FIG. 18). The plurality of initial channel layers 201 and the plurality of initial sacrificial layers 202 may be stacked vertically and alternately along a surface normal direction of the substrate 200. The plurality of initial channel layers 201 and the plurality of initial sacrificial layers 202 may extend along a direction X. The first direction X may be parallel to the surface of the substrate 200.

In one embodiment, the plurality of initial channel layers 201 and the plurality of initial sacrificial layers 202 may be formed on the substrate 200 by: forming a plurality of initial channel material films on the substrate 200 overlapping in the surface normal direction of the substrate 200 and a plurality of initial sacrificial material films between adjacent channel material films; forming a patterned layer (not shown) on the plurality of initial channel material films; and using the patterned layer as a mask to etch the plurality of channel material films and the plurality of the sacrificial material films to form the plurality of initial channel layers 201 and the plurality of initial sacrificial layers 202.

The plurality of initial sacrificial layers 202 may be made of a material different from a material of the plurality of initial channel layers 201. When forming gate structures subsequently, the plurality of initial sacrificial layers 202 may need to be removed. Therefore, the plurality of initial sacrificial layers 202 and the plurality of initial channel layers 201 with different materials may have a larger etching selectivity ratio, and damage to channel layers in the process of removing sacrificial layers may be reduced.

In one embodiment, the plurality of initial sacrificial layers 202 may be made of silicon germanium and the plurality of initial channel layers 201 may be made of silicon. In other embodiments, the plurality of initial sacrificial layers 202 may be made of a material including germanium and the plurality of initial channel layers 201 may be made of a material including silicon germanium.

As shown in FIG. 5, an isolation layer 203 may be formed on the substrate 200, and a top surface of the isolation layer 203 may be not higher than a top surface of one of the plurality of initial channel layer 201 at the bottom (e.g., S106 in FIG. 18).

In one embodiment, the isolation layer 203 may be formed by: forming an isolation material layer (not shown) on the substrate 200 to cover sidewalls of some initial channel layers 201 and some initial sacrificial layers 202; and etching back the sidewalls of the plurality of initial sacrificial layers 202 to form the isolation layer 203.

The isolation layer 203 may be made of a material including silicon oxide or silicon nitride. In the present embodiment, the isolation layer 203 may be made of silicon nitride.

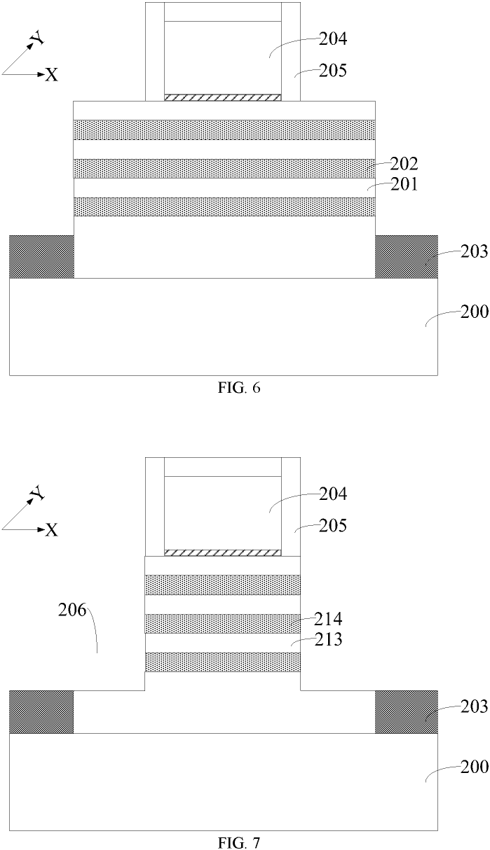

As shown in FIG. 6, after the isolation layer 203 is formed, dummy gate structures 204 and initial outer spacers 205 on sidewall surfaces of the dummy gate structures 204 may be formed on the substrate 200 (e.g., S108 in FIG. 18). The dummy gate structures 204 may cross the plurality of initial channel layers and the plurality of initial sacrificial layers along a second direction Y. The second direction Y may be perpendicular to the first direction X, and parallel to the surface of the substrate 200.

In one embodiment, each of the dummy gate structures 204 may include: a gate dielectric layer, a dummy gate layer on the gate dielectric layer, and a protection layer (not shown) on the dummy gate layer.

In one embodiment, the dummy gate layer may be made of polysilicon; in other embodiments, the dummy gate layer may be made of a material including amorphous silicon.

In one embodiment, the protective layer may be made of silicon nitride. In other embodiments, the protective layer may be made of a material including silicon oxide.

In one embodiment, the initial outer spacers 205 may be formed by: forming outer spacer material layers (not shown) on the sidewalls and top surfaces of the dummy gate structures 204 and the top surface of the isolation layer 203; and etching back the outer spacer material layers until the top surfaces of the dummy gate structures 204 and the isolation layer 203 is exposed, to form the initial outer spacers 205.

In one embodiment, the outer sidewall spacer layers may be formed by an atomic layer deposition process.

As shown in FIG. 7, the dummy gate structures 204 and the initial outer spacers 205 may be used as a mask to etch the plurality of initial channel layers 201 and the plurality of initial sacrificial layers 202, to form source/drain openings 206 and a plurality of channel layers 213 and a plurality of sacrificial layers 214 (e.g., S110 in FIG. 18).

In one embodiment, the source/drain openings 206 may provide spaces for source/drain doped layers formed subsequently.

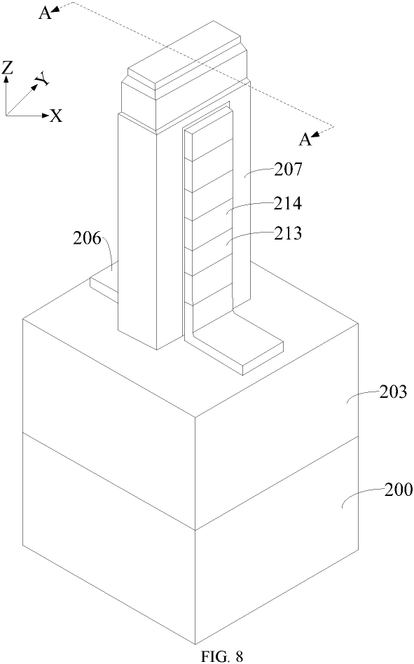

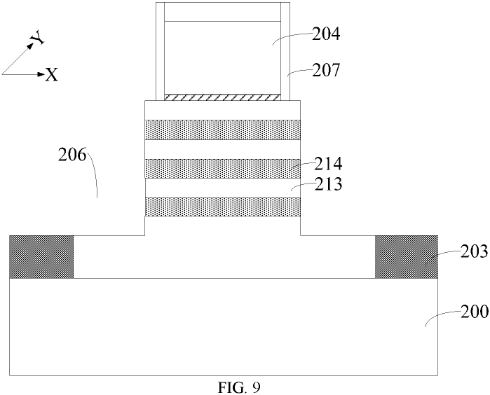

As shown in FIG. 8 which is a three-dimensional view of the semiconductor structure and FIG. 9 which is a schematic cross-sectional view along AA in FIG. 8, a dimension of the initial outer spacers 205 may be thinned to form outer spacers 207 (e.g., S112 in FIG. 18). A dimensional of the outer spacers 207 parallel to the first direction X may be smaller than a dimension of the initial outer spacers 205 parallel to the first direction X.

In one embodiment, by thinning the initial outer spacers 205, the formed outer spacers 207 may expose other two surfaces of each of the plurality of sacrificial layers 214. Correspondingly, when some of the plurality of sacrificial layers 214 are etched subsequently, the etching may easily be in contact with the three surfaces of each of the plurality of sacrificial layers 214. The difficulty of the etching process and the residue of etching by-products may be reduced, and morphology of the subsequently formed isolation grooves may be improved.

In one embodiment, the dimensional of the outer spacers 207 parallel to the first direction X may be smaller than the dimension of the initial outer spacers 205 parallel to the first direction X by about 1 nm to about 5 nm.

When the dimensional of the outer spacers 207 parallel to the first direction X may be smaller than the dimension of the initial outer spacers 205 parallel to the first direction X by a range less than 1 nm, areas of the other two surfaces of each of the plurality of sacrificial layers 214 exposed by the outer spacers 207 may be small, and the morphology of the subsequently formed isolation grooves may still have defects. When the dimensional of the outer spacers 207 parallel to the first direction X may be smaller than the dimension of the initial outer spacers 205 parallel to the first direction X by a range larger than 5 nm, a remaining thickness of the outer spacers 207 may be small, and the isolation effect of the outer spacers 207 may be affected, easily leading to the leakage problem between adjacent gate structures.

In one embodiment, the initial outer spacers 205 may be thinned by an isotropic etching process.

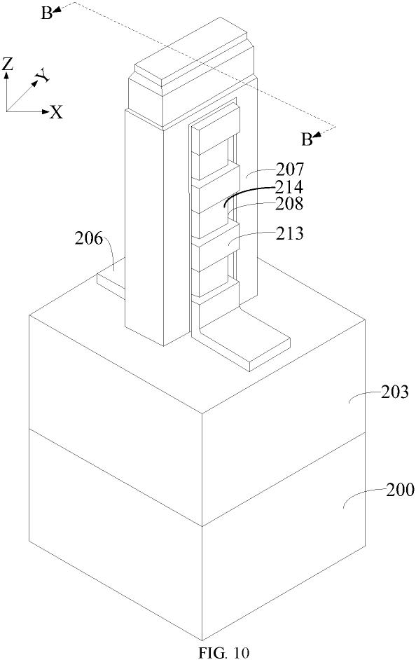

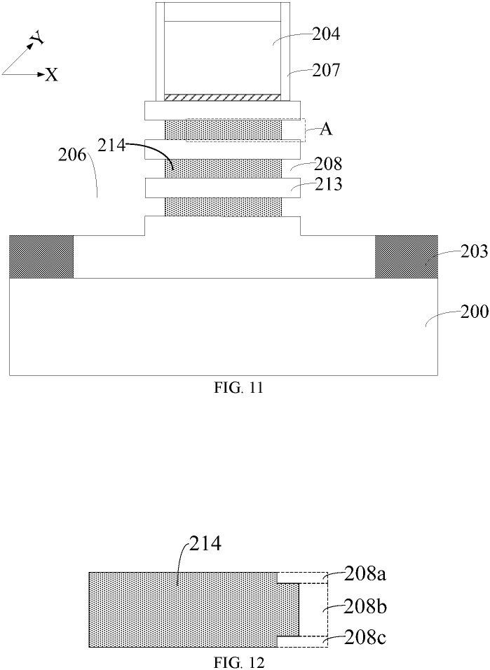

As shown in FIG. 10 which is a three-dimensional view of the semiconductor structure, FIG. 11 which is a schematic cross-sectional view along BB in FIG. 10, and FIG. 12 which is a top view of a part A in FIG. 11, a portion of the plurality of sacrificial layers 214 exposed by the source/drain openings 206 may be etched back, to form isolation grooves 208 between adjacent channel layers 213 (e.g., S114 in FIG. 18).

Since the outer spacers 207 may be formed to expose the other two surfaces of each of the plurality of sacrificial layers 214, when the portion of the plurality of sacrificial layers 214 exposed by the source/drain openings 206 is etched back, the plurality of sacrificial layers 214 located in the corner regions may contact more etching solution, such that the plurality of sacrificial layers 214 located in the corner regions may be etched faster.

Therefore, each of the finally formed isolation grooves 208 may include a first corner groove 208a, a middle groove 208b, and a second corner groove 208c arranged along the second direction Y. A size of the first corner groove 208a and a size of the second corner groove 208c along the first direction X may be larger than a size of the middle groove 208b along the first direction X.

In one embodiment, the isolation grooves 208 may be used to provide spaces for inner spacers formed later. The electrical isolation between the gate structures and the source/drain doped layers to be formed subsequently may be ensured by the inner spacers.

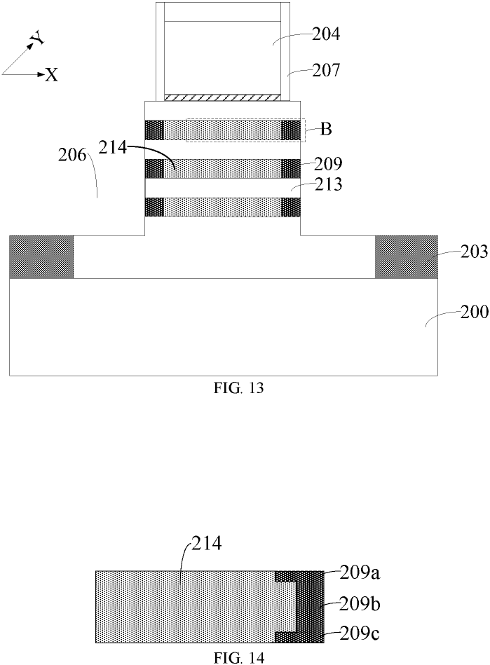

As shown in FIG. 13 with a view direction same as FIG. 11 and FIG. 14 which is a top view of a part B in FIG. 13, inner spacers 209 may be formed in the isolation grooves 208 (e.g., S116 in FIG. 18).

In one embodiment, the inner spacers 209 may be formed by: forming first initial inner spacers (not shown) in the isolation grooves 208, on sidewalls and bottom surfaces of the source/drain openings 206, on the sidewalls of the outer spacers 207, and on top surfaces of the dummy gate structures 204; etching back the first initial inner spacers until the bottom surface of the source/drain openings 206 and the top surfaces of the dummy gate structures 204 are exposed, to form second initial inner spacers (not shown); and etching back the second initial inner spacers until the sidewalls of the outer spacers 207 and the plurality of channel layers 213 are exposed, to form the inner spacers 209.

The first initial inner spacers may be formed by a physical vapor deposition process, a chemical vapor deposition process, or an atomic layer deposition process. In the present embodiment, the first initial inner spacers may be formed by the atomic layer deposition process.

Since the inner spacers 209 may fill the isolation groove 208, the morphology of the finally formed inner spacers may be consistent with the morphology of the isolation grooves 208.

Each inner spacer 209 may include a first corner layer 209a in the first corner groove 208a, a middle layer 209b in the middle groove 208b, and a second corner layer 209c in the second corner groove 208c.

Because dimensions of the first corner layer 209a in the first corner groove 208a and the second corner layer 209c in the second corner groove 208c of the inner spacer 209 are relatively large, the isolation effect of the inner spacer 209 may be effectively improved, and the occurrence of the leakage problem between the gate structures and the source/drain doped layers formed subsequently may be reduced.

In one embodiment, the inner spacers 209 may be made of a material including silicon nitride.

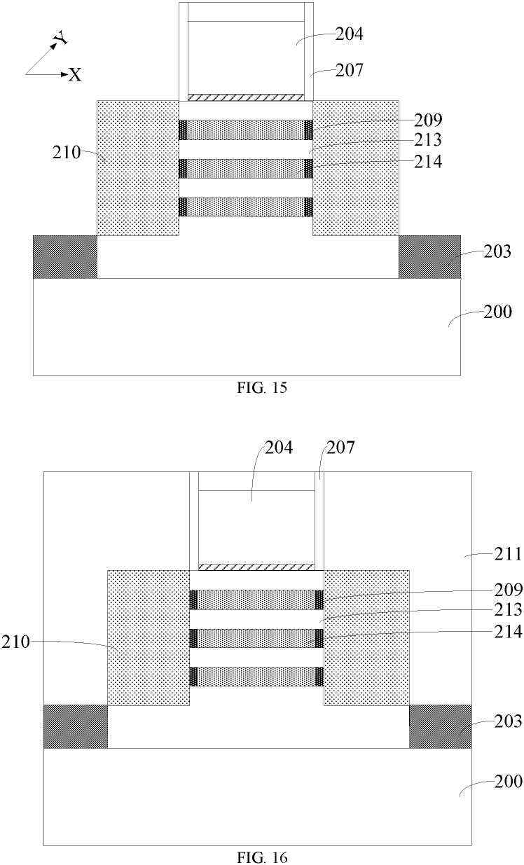

As shown in FIG. 15, after the inner spacers 209 are formed, a source/drain doped layer 210 may be formed in each source/drain opening 206. The source/drain doped layer 210 may include source/drain ions. A surface of the source/drain doped layer 210, a surface of a corresponding inner spacer 209, and an end surface of a corresponding channel layer 213 may be vertically coplanar.

In one embodiment, since the initial outer spacers 205 may be thinned, the formed outer spacers 207 may also expose the other two surfaces of each of the plurality of channel layers 213. A contact area between the source/drain doped layer 210 and the corresponding channel layer 213 may be increased, which may be beneficial to improve the operating current of the device.

In one embodiment, the source/drain doped layer 210 may be formed by an epitaxial growth process. The source/drain doped layer 210 may be doped with source/drain ions by an in-situ doping process.

When the semiconductor structure is a P-type device, the source/drain doping layer 210 may be made of a material including silicon, germanium or silicon germanium, and the source/drain ions may be P-type ions including boron ions, BF2 -ion or indium ion. When the semiconductor structure is an N-type device, the source/drain doping layer 210 may be made of a material including silicon, gallium arsenide or indium gallium arsenide, and the source/drain ions may be N-type ions including phosphorus ions or arsenic ions.

In the present embodiment, the semiconductor structure may be an N-type device. the source/drain doping layer 210 may be made of silicon, and the source/drain ions may be phosphorus ions.

As shown in FIG. 16, after the source/drain doped layer 210 is formed, a dielectric layer 211 may be formed on the isolation layer 203 (e.g., S118 in FIG. 18). The dielectric layer 211 may cover the dummy gate structures 204, the plurality of channel layers 213, and the plurality of sacrificial layers 214. The dielectric layer 211 may expose the top surfaces of the dummy gate structures 204.

In one embodiment, the dielectric layer 211 may be formed by: forming an initial dielectric layer (not shown) on source/drain doped layers 210 and the dummy gate structures 204 where the initial dielectric layer covers the top surfaces and sidewall surfaces of the dummy gate structures 204; planarizing the initial dielectric layer until the surface of the protective layers on the tops of the dummy gate structures 204 are exposed, to form the dielectric layer 211.

In one embodiment, the dielectric layer 211 may be made of a material including silicon oxide.

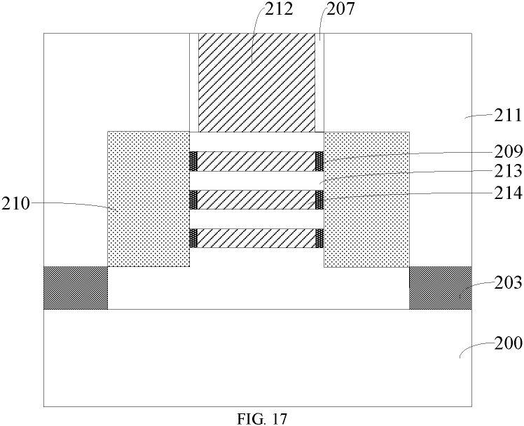

As shown in FIG. 17, after the dielectric layer 211 is formed, the dummy gate structures 204 may be removed to form gate openings (not shown) in the dielectric layer 211. A portion of the plurality of sacrificial layers 214 exposed by the gate openings may be removed to form gate grooves between adjacent channel layers 213. Gate structures 212 may be formed in the gate openings and the gate grooves. Each gate structure 212 may surround a corresponding channel layer 213.

In one embodiment, each gate structure 212 may include a gate layer.

The gate layer may be made of a metal including copper, tungsten, nickel, chromium, titanium, tantalum, aluminum, or a combination thereof. In the present embodiment, the gate layer may be made of tungsten.

The present disclosure also provides a semiconductor structure. In one embodiment, as shown in FIG. 17, the semiconductor structure may include: a substrate 200; a plurality of channel layers 213 on the substrate 200; an isolation layer 203 located on the substrate 200; isolation grooves 208 between ends of adjacent channel layers 213; inner spacers 209 in the isolation grooves 208; gate structures 212 on the isolation layer 203; outer spacers 207 on sidewall surfaces of the gate structures 212; source/drain doped layers 210 at two sides of each gate structure 212; and a dielectric layer 211 on the isolation layer 203. The plurality of channel layers 213 may be vertically stacked along a surface normal direction of the substrate 200, and may extend along a first direction X. The first direction X may be parallel to the surface of the substrate 200. A top surface of the isolation layer 203 may be not higher than a top surface of one of the plurality of channel layers 213 at the bottom. The inner spacers 209 may be used to vertically isolate the plurality of channel layers 213 along the surface normal direction of the substrate 200, such that adjacent channel layers 213 are suspended. The gate structures 212 may surround the plurality of channel layers 213 along a second direction Y. The second direction Y may be perpendicular to the first direction X and parallel to the surface of the substrate 200. In the first direction X, sidewalls of the outer spacers 207 may be recessed with respect to end faces of the plurality of channel layers 213. A surface of a source/drain doped layer 210, the surfaces of the corresponding inner spacers 209, and the end surfaces of a corresponding channel layer 213 may be vertically coplanar. The dielectric layer 211 may cover the gate structures 212 and the plurality of channel layers 213, and may expose the top surfaces of the gate structures 212.

In the present disclosure, the outer spacers 207 may be located on the sidewall surfaces of the gate structures 212, and in the first direction X, the sidewalls of the outer spacers 207 may be recessed with respect to the end surfaces of the plurality of channel layers 213. By thinning initial outer spacers, the formed outer spacers 207 may expose other two sides of each of the plurality of sacrificial layers 214. Correspondingly, in the process of forming the isolation grooves 208, etching may be easily in contact with the three surfaces of each of the plurality of sacrificial layers 214, which may reduce the difficulty of the etching process, reduce the residue of etching by-products, and improve the profiles of the isolation grooves 208.

Further, since the sidewalls of the outer spacers 207 may be recessed with respect to the end surfaces of the plurality of channel layers 213, the outer spacers 207 may expose other two sides of each of the plurality of channel layers 213, therefore ensuring contact areas between the source/drain doped layers 210 and the plurality of channel layers 213 are increased to improve the working current of the device.

Each of the isolation grooves 208 may include a first corner groove 208a, a middle groove 208b, and a second corner groove 208c arranged along the second direction Y. A size of the first corner groove 208a and a size of the second corner groove 208c along the first direction X may be larger than a size of the middle groove 208b along the first direction X.

Each inner spacer 209 may include a first corner layer 209a in the first corner groove 208a, a middle layer 209b in the middle groove 208b, and a second corner layer 209c in the second corner groove 208c. Since dimensions of the first corner layer 209a in the first corner groove 208a and the second corner layer 209c in the second corner groove 208c of the inner spacer 209 are relatively large, the isolation effect of the inner spacer 209 may be effectively improved, and the occurrence of the leakage problem between the gate structures and the source/drain doped layers formed subsequently may be reduced.

In one embodiment, the sidewalls of the outer spacers 207 may be recessed with respect to the end surfaces of the plurality of channel layers 213 by about 1 nm to about 5 nm.

When the sidewalls of the outer spacers 207 may be recessed with respect to the end surfaces of the plurality of channel layers 213 by a range less than 1 nm, areas of the other two surfaces of each of the plurality of sacrificial layers 214 exposed by the outer spacers 207 may be small, and the morphology of the subsequently formed isolation grooves may still have defects. When the sidewalls of the outer spacers 207 may be recessed with respect to the end surfaces of the plurality of channel layers 213 by a range larger than 5 nm, a remaining thickness of the outer spacers 207 may be small, and the isolation effect of the outer spacers 207 may be affected, easily leading to the leakage problem between adjacent gate structures.

In one embodiment, the inner spacers 209 may be made of a material including SiNx.

The embodiments disclosed herein are exemplary only. Other applications, advantages, alternations, modifications, or equivalents to the disclosed embodiments are obvious to those skilled in the art and are intended to be encompassed within the scope of the present disclosure.

What is claimed is:

1. A semiconductor structure, comprising:
a substrate;
a plurality of channel layers on the substrate, wherein the plurality of channel layers are vertically stacked along a normal direction of a surface of the substrate and extend along a first direction parallel to the surface of the substrate, wherein isolation grooves are formed between ends of adj acent channel layers of the plurality of channel layers;
an isolation layer on the substrate, wherein a top surface of the isolation layer is not higher than a top surface of any of the plurality of channel layers,;
inner spacers in the isolation grooves, wherein the inner spacers vertically isolate the plurality of channel layers along the normal direction of the surface of the substrate such that the adjacent channel layers are suspended;
gate structures over the isolation layer, wherein the gate structures surround a portion of the plurality of channel layers along a second direction perpendicular to the first direction and parallel to the surface of the substrate;
outsider spacers at sidewalls of the gate structures, wherein sidewalls of the outside spacers are recessed with respect to end surfaces of the plurality of channel layers;
source/drain doped layers at two sides of each gate structure, wherein surfaces of the source/drain doped layers, surfaces of the inner spacers, and the end surfaces of the plurality of channel layers are vertically coplanar; and a dielectric layer over the isolation layer, wherein the dielectric layer covers a portion of the plurality of channel layers and the gate structures and exposes top surfaces of the gate structures.

2. The structure according to claim 1, wherein:
each of the isolation grooves includes a first corner groove, a middle groove, and a second corner groove arranged along the second direction; and
each of a size of the first corner groove and a size of the second corner groove along the first direction is larger than a size of the middle groove along the first direction.

3. The structure according to claim 2, wherein each of the inner spacers includes a first corner layer in the first corner groove, a middle layer in the middle groove, and a second corner layer in the second corner groove.

4. The structure according to claim 1, wherein the sidewalls of the outer spacers are recessed with respect to the end surfaces of the plurality of channel layers by about 1 nm to about 5 nm.

5. The structure according to claim 1, wherein the inner spacers are made of a material including silicon nitride.

6. A fabrication method of a semiconductor structure, comprising:
providing a substrate;
forming a plurality of initial channel layers and a plurality of initial sacrificial layers on the substrate, wherein the plurality of initial channel layers and the plurality of initial sacrificial layers are stacked vertically and alternately along a normal direction of a surface of the substrate and extend along a first direction parallel to the surface of the substrate;
forming an isolation layer on the substrate, wherein a top surface of the isolation layer is not higher than a top surface of one of the plurality of initial channel layers at the bottom;
forming dummy gate structures on the substrate and initial outer spacers on sidewall surfaces of the dummy gate structures, wherein the dummy gate structure crosses a portion of the plurality of initial channel layers and a portion of the plurality of initial sacrificial layers along a second direction perpendicular to the first direction and parallel to the surface of the substrate;
using the dummy gate structures and the initial outer spacers as a mask to remove a portion of the plurality of initial channel layers and a portion of the plurality of the initial sacrificial layers, to form source/drain openings, a plurality of channel layers, and a plurality of sacrificial layers;
after forming the source/drain openings, thinning the initial outer spacers to form outer spacers, wherein a size of the outer spacers parallel to the first direction is smaller than a size of the initial outer spacers parallel to the first direction;
etching back a part of the plurality of sacrificial layers exposed by the source/drain openings, to form isolation grooves between adjacent channel layers;
forming inner spacers in the isolation grooves;
forming source/drain doped layers in the source/drain openings, wherein surfaces of the source/drain doped layers, surfaces of the inner spacers and end faces of the plurality of channel layers are vertically coplanar; and
forming a dielectric layer on the isolation layer, wherein the dielectric layer covers a portion of the plurality of channel layers and the dummy gate structure and exposes top surfaces of the dummy gate structures.

7. The method according to claim 6, wherein:
each of the isolation grooves includes a first corner groove, a middle groove, and a second corner groove arranged along the second direction; and
each of a size of the first corner groove and a size of the second corner groove along the first direction is larger than a size of the middle groove along the first direction.

8. The method according to claim 7, wherein:
each of the inner spacers includes a first corner layer in the first corner groove, a middle layer in the middle groove, and a second corner layer in the second corner groove.

9. The method according to claim 6, wherein:
the size of the outer spacers parallel to the first direction is smaller than the size of the initial outer spacers parallel to the first direction by about 1 nm to about 5 nm.

10. The method according to claim 6, wherein:
the initial outer spacers are thinned by an isotropic etching process.

11. The method according to claim 6, wherein forming the inner spacers includes:
forming first initial inner spacers in the isolation grooves, on sidewalls and bottom surfaces of the source/drain openings, on the sidewalls of the outer spacers, and on top surfaces of the dummy gate structures;
etching back the first initial inner spacers until the bottom surface of the source/drain openings and the top surfaces of the dummy gate structures are exposed, to form second initial inner spacers; and
etching back the second initial inner spacers until the sidewalls of the outer spacers and the plurality of channel layers are exposed, to form the inner spacers.

12. The method according to claim 11, wherein:
the first initial inner spacers are formed by a physical vapor deposition process, a chemical vapor deposition process, or an atomic layer deposition process.

13. The method according to claim 6, wherein:
the first initial inner spacers are made of a material including silicon nitride.

14. The method according to claim 6, after forming the dielectric layer, further including:
removing the dummy gate structures to form gate openings in the dielectric layer;
removing a portion of the plurality of sacrificial layers exposed by the gate openings to form gate grooves between adjacent channel layers; and
forming a gate structure in each gate opening and a corresponding gate groove, wherein the gate structure surrounds a corresponding one of the plurality of channel layers.

15. The method according to claim 6, wherein the plurality of sacrificial layers and the plurality of channel layers are made of different materials.

16. The method according to claim 6, wherein:
the plurality of sacrificial layer is made of a material including silicon germanium; and
the plurality of channel layers is made of a material including silicon.
